(19) United States
(12) Patent Application Publication
(10) Pub. No.: US 2022/0020696 A1
(43) Pub. Date: Jan. 20, 2022

(54) WORKPIECE MANAGEMENT METHOD AND SHEET CUTTING MACHINE

(71) Applicant: DISCO CORPORATION, Tokyo (JP)

(72) Inventors: Yoshinobu SAITO, Tokyo (JP); Daisuke YAMASHITA, Tokyo (JP)

(21) Appl. No.: 17/379,518

(22) Filed: Jul. 19, 2021

(30) Foreign Application Priority Data
Jul. 20, 2020 (JP) 2020-123649

(51) Int. Cl. H01L 23/544; H01L 21/78; H01L 21/683; B41M 5/26; B28D 5/00; B23K 26/38

(52) U.S. Cl. CPC H01L 23/544; H01L 21/78; H01L 21/6836; H01L 2223/5448; B28D 5/0029; B23K 26/38; H01L 2223/54413; B41M 5/26

(57) ABSTRACT

A workpiece management method includes a frame unit forming step of forming a frame unit with a workpiece supported in an opening of an annular frame via a resin sheet, a printing step of, after performing the frame unit forming step, printing identification information of the workpiece on the resin sheet in an area between an outer periphery of the workpiece and an inner periphery of the annular frame, a processing step of processing the workpiece by a processing machine, a separation step of separating the processed workpiece from the resin sheet, and a storage step of storing the resin sheet from which the workpiece has been separated. A sheet cutting machine suitable for use in the workpiece management method is also disclosed.

### BACKGROUND OF THE INVENTION

### Field of the Invention

The present invention relates to a workpiece management method and a sheet cutting machine.

### Description of the Related Art

Diverse electronic equipment is fabricated using device chips formed by dividing various plate-shaped workpieces such as semiconductor wafers, resin package substrates, glass substrates, and ceramic substrates. For processing a workpiece, a frame unit, with the workpiece supported in an opening of an annular frame via a resin sheet such as an adhesive tape, is formed in order to permit handling the workpiece without damage during manufacture (see, for example, JP Hei 10-242083A). A frame unit is often adopted especially in a dicing step including a cutting step by a cutting blade or a processing step with a laser beam, a device inspection step, and a chip separation (pickup) step.

### SUMMARY OF THE INVENTION

In recent years, it is required to make a record of what circumstances were in each processing step in order to determine the cause of any defective product if it occurs in manufactured device chips. Processing circumstances of a workpiece, on which a defect occurred, in all processing steps may be determined, for example, by forming a bar code or the like on the workpiece, reading the bar code in every processing machine or apparatus, recording when and in which processing machines or apparatus the workpiece was processed, and checking log date from all the processing machines or apparatus.

If a lot of residual debris remains on a dicing tape after pickup of device chips, there is a high possibility that many of the device chips underwent chipping at their surfaces on a side of the dicing tape. Therefore, the dicing tape after performance of the pickup step may be stored, and how the workpiece was processed may be kept as a record for a given period of time. It is, however, unable to determine which workpiece was fixed on the dicing tape, thereby making it difficult to conduct a detailed investigation on the cause of such a lot of residual debris.

The present invention therefore has as objects thereof the provision of a workpiece management method and a sheet cutting machine, which can reduce the difficulty in conducting an investigation on the cause of a defect of a device chip.

In accordance with an aspect of the present invention, there is provided a workpiece management method including a frame unit forming step of forming a frame unit with a workpiece that has a front surface, the front surface including devices formed in respective regions defined by a plurality of intersecting streets, and that supported in an opening of an annular frame via a resin sheet, a printing step of, after performing the frame unit forming step, printing identification information of the workpiece on the resin sheet in an area between an outer periphery of the workpiece and an inner periphery of the annular frame, a processing step of processing the workpiece by a processing machine, a separation step of separating the processed workpiece from the resin sheet, and a storage step of storing the resin sheet from which the workpiece has been separated.

Preferably, the workpiece management method may further include an inspection result acquisition step of, after performing the printing step and the separation step, inspecting processed conditions from a processed mark remaining on the resin sheet, reading the identification information on the inspected resin sheet, and acquiring the processed conditions of the workpiece in association with the identification information.

Preferably, the identification information may include identification information of the workpiece, processing conditions in the processing step for the workpiece, or information regarding a date on which the processing step was performed on the workpiece.

In accordance with another aspect of the present invention, there is provided a sheet cutting machine including a cassette mount section configured to mount thereon a cassette that holds a frame unit, the frame unit being formed from an annular frame and a workpiece supported in an opening of the annular frame via a resin sheet, after processing of the workpiece, formation of a processed mark on the resin sheet, and separation of the processed workpiece from the resin sheet, an unloading unit configured to unload the frame unit from the cassette mounted on the cassette mount section, a printing unit configured to print identification information of the separated workpiece on the resin sheet of the frame unit unloaded from the cassette, a resin sheet separation unit configured to separate the resin sheet, the resin sheet remaining on the frame unit and carrying the identification information printed by the printing unit, from the annular frame, and a resin sheet holding section configured to hold the resin sheet separated from the annular frame by the resin sheet separation unit.

The workpiece management method and the sheet cutting machine of the present invention can bring about an advantageous effect that the difficulty in conducting an investigation on the cause of a defect of a device chip can be reduced.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view depicting an example of a workpiece as an object of management by a workpiece management method according to a first embodiment;

FIG. 2 is a flow chart illustrating a flow of the workpiece management method according to the first embodiment;

FIG. 3 is a perspective view illustrating a frame unit formation step in the workpiece management method illustrated in FIG. 2;

FIG. 4 is a perspective view depicting a frame unit formed in the frame unit formation step in the workpiece management method illustrated in FIG. 2;

FIG. 5 is a cross-sectional view illustrating a printing step in the workpiece management method illustrated in FIG. 2;

FIG. 6 is a perspective view depicting the frame unit after the printing step in the workpiece management method illustrated in FIG. 2;

FIG. 7 is a plan view of identification information of the frame unit depicted in FIG. 6;

FIG. 8 is a side view illustrating a processing step in the workpiece management method illustrated in FIG. 2, in which some elements are illustrated in cross-section;

FIG. 9 is a perspective view depicting the frame unit after the processing step in the workpiece management method illustrated in FIG. 2;

FIG. 10 is a side view illustrating a separation step in the workpiece management method illustrated in FIG. 2, in which some elements are illustrated in cross-section;

FIG. 11 is a perspective view illustrating an example of a storage step in the workpiece management method illustrated in FIG. 2;

FIG. 12 is a perspective view depicting a cassette for use in another example of the storage step in the workpiece management method illustrated in FIG. 2;

FIG. 13 is a flow chart illustrating a flow of a workpiece management method according to a second embodiment;

FIG. 14 is a perspective view illustrating an inspection result acquisition step in the workpiece management method illustrated in FIG. 13;

FIG. 15 is a view illustrating an image of an essential part of a resin sheet obtained in the inspection result acquisition step in the workpiece management method illustrated in FIG. 13;

FIG. 16 is a flow chart illustrating a flow of a workpiece management method according to a third embodiment;

FIG. 17 is a perspective view depicting a frame unit after a separation step in the workpiece management method illustrated in FIG. 16;

FIG. 18 is a plan view schematically illustrating a configuration of a sheet cutting machine that performs a printing step in the workpiece management method illustrated in FIG. 16;

FIG. 19 is a side view illustrating a state where a resin sheet is cut along an inner edge of an annular frame in the printing step in the workpiece management method illustrated in FIG. 16, in which some elements are illustrated in cross-section;

FIG. 20 is a side view illustrating a state where a resin sheet cut in the printing step in the workpiece management method illustrated in FIG. 16 is held, in which some elements are illustrated in cross-section; and

FIG. 21 is a cross-sectional view illustrating a state where the resin sheet is held in a holder case in the printing step in the workpiece management method illustrated in FIG. 16.

### DETAILED DESCRIPTION OF THE PREFERRED EMBODIMENTS

With reference to the attached drawings, a description will be made in detail about embodiments of the present invention. However, the present invention shall not be limited by details that will be described in the subsequent embodiments. The elements of configurations that will hereinafter be described include those readily conceivable to persons skilled in the art and substantially the same ones. Further, the configurations that will hereinafter be described can be combined appropriately. Furthermore, various omissions, replacements, and modifications of configurations can be made without departing from the spirit of the present invention.

### First Embodiment

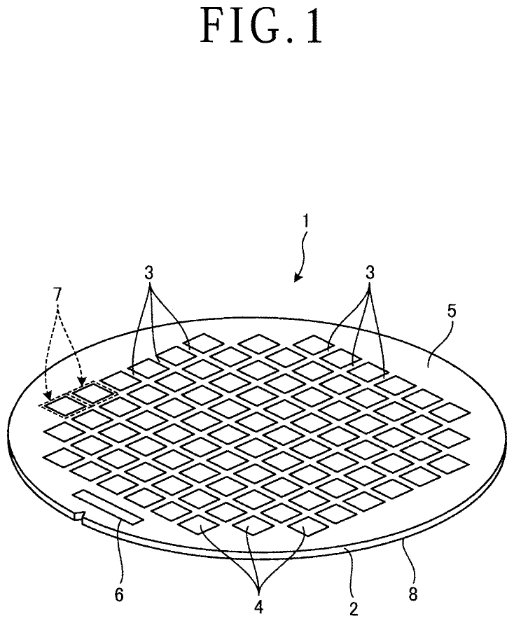

A workpiece management method according to a first embodiment of the present invention will be described with reference to FIGS. 1 through 12.

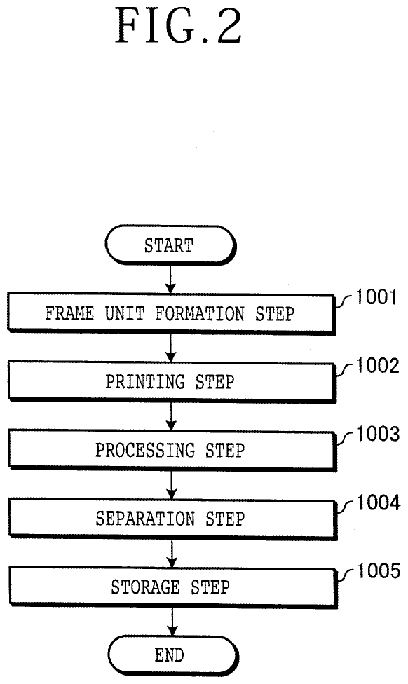

FIG. 1 is a perspective view depicting an example of a workpiece as an object of management by a workpiece management method according to a first embodiment. FIG. 2 is a flow chart illustrating a flow of the workpiece management method according to the first embodiment.

The workpiece management method according to the first embodiment can be applied, for example, to a workpiece 1 depicted in FIG. 1. The workpiece 1 is an object of management by the workpiece management method according to the first embodiment, and is a disc-shaped wafer, such as a semiconductor wafer or an optical device wafer, including a substrate 2 of silicon (Si), sapphire (Al₂O₃), gallium arsenide (GaAs) or silicon carbide (SiC).

As depicted in FIG. 1, the workpiece 1 has a front surface 5 including devices 4 formed in respective regions defined by a plurality of intersecting dicing lines (hereinafter called “streets”) 3. The devices 4 are, for example, integrated circuits (ICs) such as ICs or large scale integrations (LSIs) or image sensors such as charge coupled devices (CCD) or complementary metal oxide semiconductors (CMOS).

In the workpiece 1, workpiece identification (ID) information 6 is applied to the front surface 5 of the substrate 2. The workpiece ID information 6 is information for identifying each workpiece 1, in other words, is ID information of each workpiece 1. In the first embodiment, the workpiece 1 is cut (equivalent to “processed”) along the streets 3 and is divided into individual device chips 7. The device chips 7 each include a portion of the substrate 2 and the device 4.

The workpiece management method according to the first embodiment includes, as illustrated in FIG. 2, a frame unit formation step 1001, a printing step 1002, a processing step 1003, a separation step 1004, and a storage step 1005.

### (Frame Unit Formation Step)

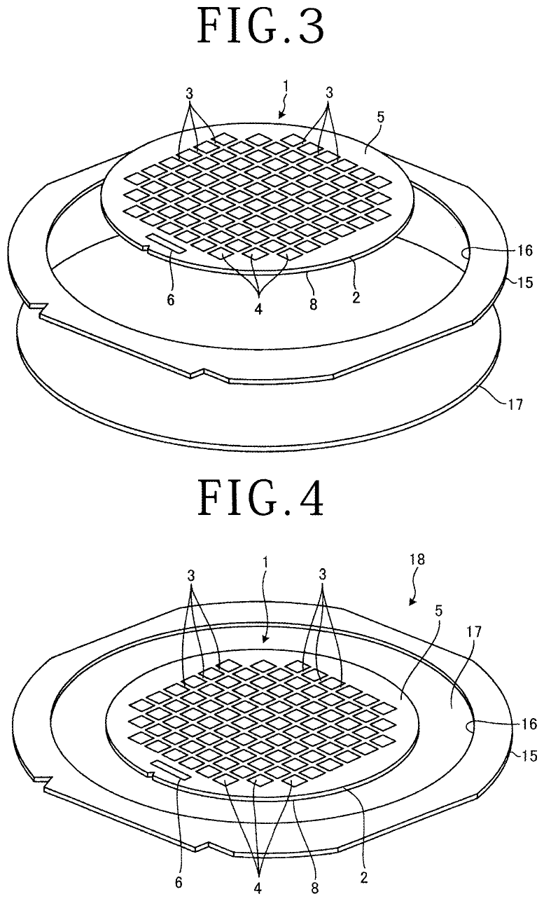

FIG. 3 is a perspective view illustrating a frame unit formation step in the workpiece management method illustrated in FIG. 2. FIG. 4 is a perspective view depicting a frame unit formed in the frame unit formation step in the workpiece management method illustrated in FIG. 2. The frame unit formation step 1001 forms a frame unit 18 with the workpiece 1 supported in an opening 16 of an annular frame 15 via a resin sheet 17.

In the frame unit formation step 1001, as illustrated in FIG. 3, the resin sheet 17 of a greater diameter than the workpiece 1 is brought at an outer edge portion of an adhesive layer thereof into opposition to the annular frame 15 having an inner diameter greater than an outer diameter of the workpiece 1, whereby the workpiece 1 is brought at a back surface 8 on a back side of the front surface 5 thereof into opposition to a central portion of the adhesive layer of the resin sheet 17. The outer edge portion of the adhesive layer of the resin sheet 17 is then bonded to the annular frame 15, followed by bonding of the back surface 8 of the workpiece 1 to the central portion of the adhesive layer of the resin sheet 17. In the frame unit formation step 1001 in the first embodiment, the frame unit 18 depicted in FIG. 4 is therefore formed with the workpiece 1 supported inside the opening 16 by the annular frame 15 via the resin sheet 17.

### (Printing Step)

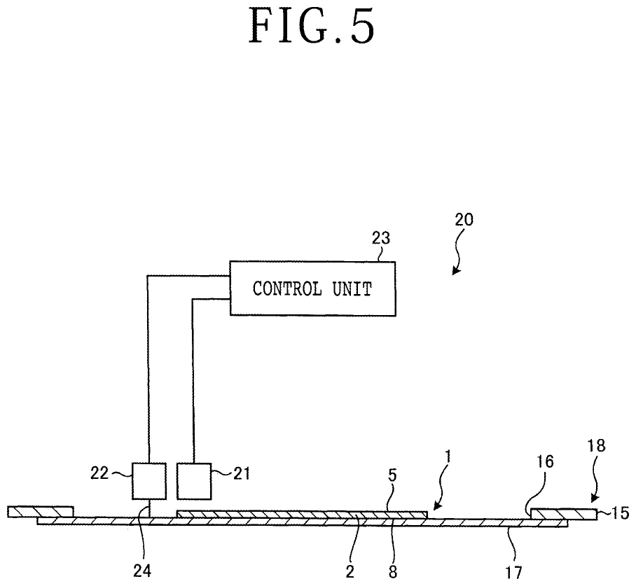

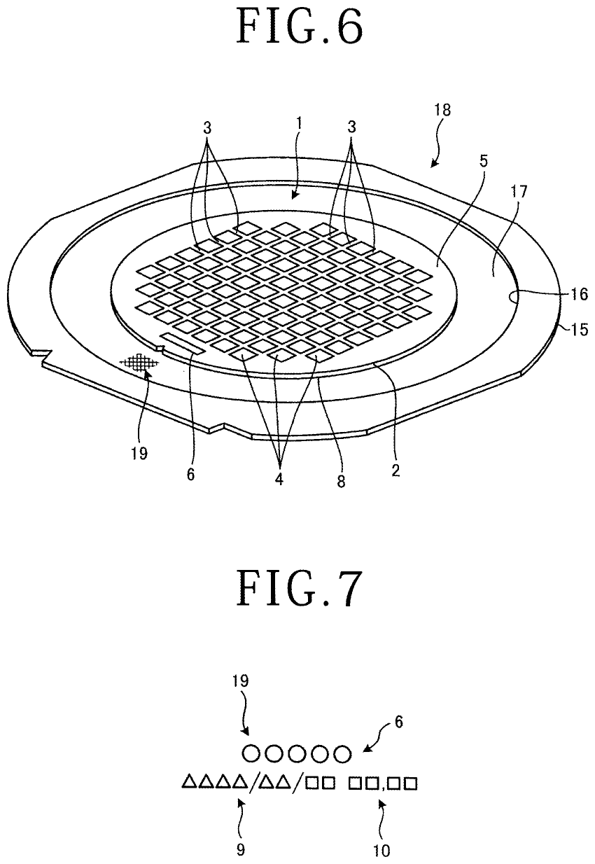

FIG. 5 is a cross-sectional view illustrating a printing step in the workpiece management method illustrated in FIG. 2. FIG. 6 is a perspective view depicting the frame unit after the printing step in the workpiece management method illustrated in FIG. 2. FIG. 7 is a plan view of identification information of the frame unit depicted in FIG. 6. After performing the frame unit formation step 1001, the printing step 1002 prints identification information 19 of the workpiece 1 on the adhesive layer of the resin sheet 17 in an area between an outer periphery of the workpiece 1 and an inner periphery of the annular frame 15.

In the printing step 1002, a printing apparatus 20 holds on an unillustrated holding table the resin sheet 17 of the frame unit 18 on a side of a base material layer thereof, and reads the workpiece ID information 6 by a reading unit 21. The printing apparatus 20 includes a control unit 23, in which the ID information of each workpiece 1 indicated by the workpiece ID information 6 thus read and processing conditions in the processing step are stored beforehand in association with each other.

The control unit 23 is a computer which includes a logic processing unit having a microprocessor such as a central processing unit (CPU), a storage device having a memory such as a read only memory (ROM) or a random access memory (RAM), and an input/output interface device, and can perform computer programs. The control unit 23 controls individual elements that make up the printing apparatus 20 and allows the printing apparatus 20 to perform the printing step 1002.

In the printing step 1002, the control unit 23 of the printing apparatus 20 extracts the processing conditions in the processing step, which are associated with the ID information of the specific workpiece 1 indicated by the workpiece ID information 6 thus read, and creates the identification information 19. In the printing step 1002, the printing apparatus 20, as illustrated in FIG. 5, brings a printing unit 22 into opposition to the adhesive layer of the resin sheet 17 in the area between the outer periphery of the workpiece 1 and the inner periphery of the annular frame 15 and, as depicted in FIG. 6, prints the identification information 19, which has been created by the control unit 23, on the adhesive layer of the resin sheet 17 in the above-described area by the printing unit 22. In the first embodiment, the printing unit 22 prints the identification information 19 by irradiating a laser beam 24 to the adhesive layer of the resin sheet 17. In the present invention, however, the printing method is not limited to such laser printing, and the identification information 19 may be printed, for example, by applying ink to the adhesive layer of the resin sheet 17.

In the first embodiment, the identification information 19 formed in the printing step 1002 includes, as illustrated in FIG. 7, the workpiece ID information 6 represented by open circles, processing condition ID information 9 represented by open triangles, and date information 10 represented by white squares. The workpiece ID information 6 is information for identifying each workpiece 1, that is, ID information of the specific workpiece 1. The processing condition ID information 9 is information indicating processing conditions in the processing step 1003 and is information for identifying each set of processing conditions, that is, ID information of the specific set of processing conditions.

Further, the processing condition ID information 9 of the identification information 19 indicates the set of processing conditions in the processing step, which is associated with the ID information of the specific workpiece 1 as indicated by the workpiece ID information 6 read by the reading unit 21. The date information 10 is information regarding the date on which the processing step 1003 was performed or the date on which the identification information 19 was printed and, in the first embodiment, indicates the date on which the processing step 1003 was performed. In the first embodiment, the control unit 23 of the printing apparatus 20 therefore creates the identification information 19 which includes the workpiece ID information 6 thus read, the processing condition ID information 9 indicating the set of processing conditions in the processing step associated with the ID information of the specific workpiece 1 as indicated by the workpiece ID information 6 thus read, and the date information 10 indicating the date on which the processing step 1003 was performed.

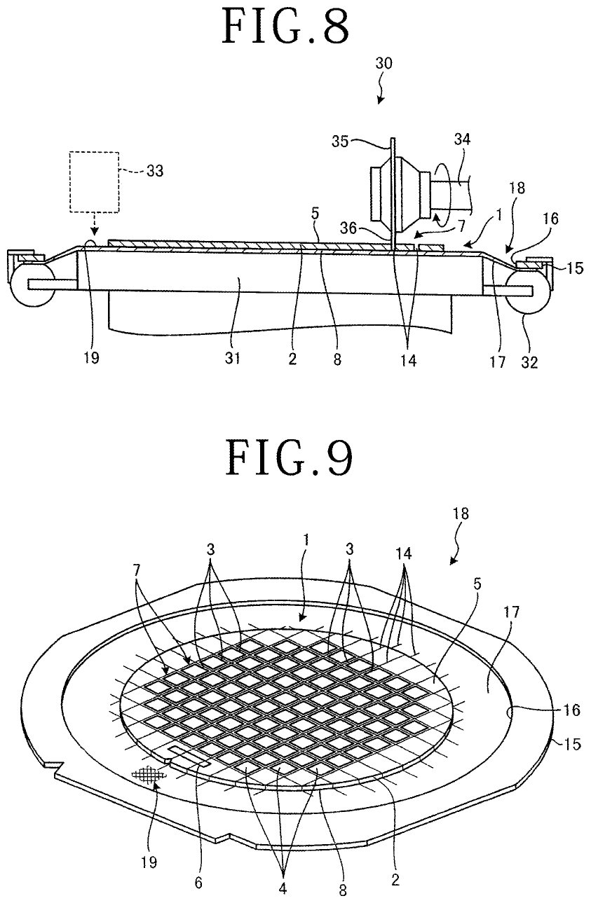

In the present invention, the identification information 19 may also be a one-dimensional bar code or two-dimensional bar code, which includes the workpiece ID information 6, the processing condition ID information, and the date information 10. In a case of a bar code, the identification information 19 may include, instead of the processing condition ID information, the type of a cutting blade 35 (see FIG. 8), a blade height that indicates the height of a lower extremity of a cutting edge 36, a Y index that indicates a distance over which the cutting blade 35 is moved in a Y-axis direction, a processing feed rate that indicates a moving speed of a chuck table 31 (see FIG. 8), a spindle rotation speed that indicates a rotational speed of a spindle 34 (see FIG. 8), and the like, all of which are specified in the set of processing conditions indicated by the processing condition ID information 9.

In the first embodiment, the identification information 19 includes the workpiece ID information 6, the processing condition ID information 9, and the date information 10. In the present invention, however, it is sufficient for the identification information 19 to include at least one of the workpiece ID information 6, the processing condition ID information 9, and the date information 10. In other words, the identification information 19 is required to include the workpiece ID information 6, the processing condition ID information 9, or the date information 10 in the present invention.

### (Processing Step)

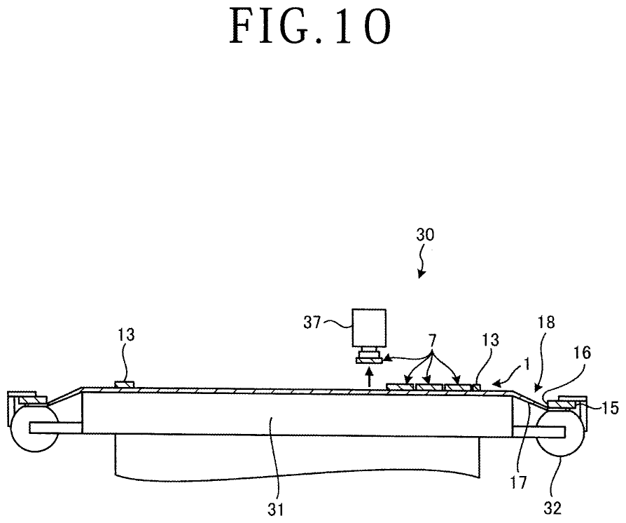

FIG. 8 is a side view illustrating a processing step in the workpiece management method illustrated in FIG. 2, in which some elements are illustrated in cross-section. FIG. 9 is a perspective view depicting the frame unit after the processing step in the workpiece management method illustrated in FIG. 2. The processing step 1003 is a step that processes the workpiece 1 by a processing machine 30.

In the processing step 1003, the processing machine 30 holds the back surface 8 of the workpiece 1 under suction on the chuck table 31 via the resin sheet 17, and clamp portions 32 clamp the annular frame 15. The processing machine 30 reads the identification information 19 by a reading unit 33, thereby extracting the set of processing conditions indicated by the processing condition ID information 9 in the identification information 19. While the cutting blade 35, which is being rotated by the spindle 34 under the processing conditions extracted by the processing machine 30, and the workpiece 1 are sequentially being moved relative to each other along the streets 3, the cutting edge 36 of the cutting blade 35 is positioned at the height where the cutting edge 36 can cut into the resin sheet 17 and is then caused to cut into the streets 3, whereby the workpiece 1 is divided into the individual device chips 7.

In the frame unit 18 after the processing step 1003, cut grooves 14 are formed as processed marks along the individual streets 3 on the workpiece 1 as depicted in FIG. 9. In the frame unit 18 after the processing step 1003, the cut grooves 14 as the processed marks also extend to the resin sheet 17 as depicted in FIG. 9. As described above, in the first embodiment, the processing machine 30 that performs the processing step 1003 is a cutting machine that cuts the workpiece 1.

### (Separation Step)

FIG. 10 is a side view illustrating a separation step 1004 in the workpiece management method illustrated in FIG. 2, in which some elements are illustrated in cross-section. The separation step 1004 is a step that separates the processed workpiece 1 from the resin sheet 17.

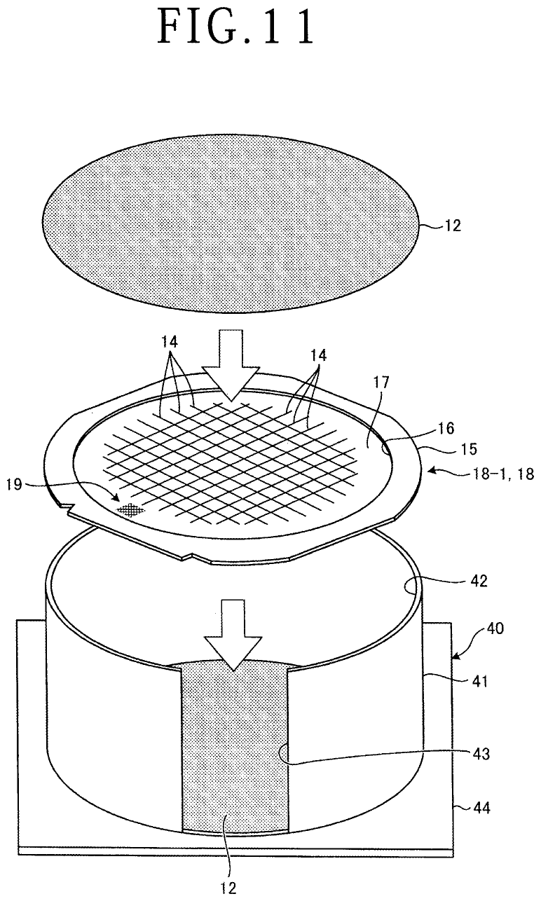

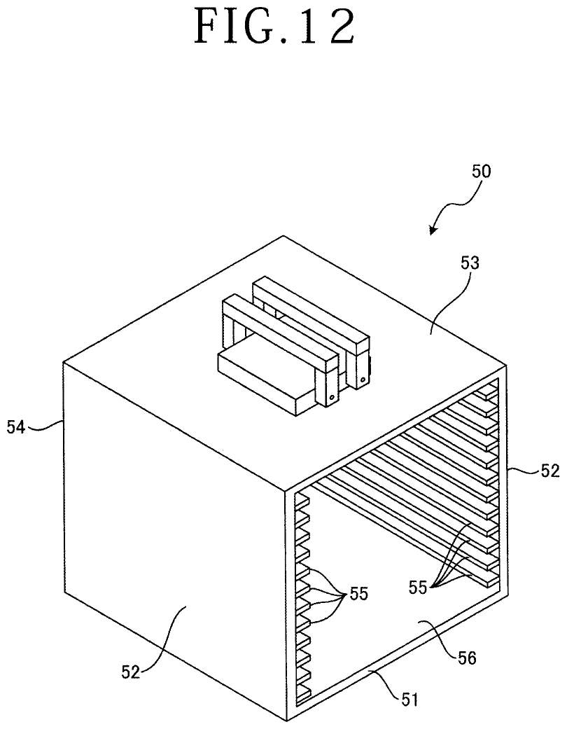

In the separation step 1004, as illustrated in FIG. 10, the device chips 7 on the workpiece 1 are separated one after one by a known pickup device 37 from the adhesive layer of the resin sheet 17, so that all the device chips 7 are picked up. Actually, cutoff chips remain on the frame unit 18 illustrated in FIG. 11 although such cutoff chips are omitted in FIG. 11. The frame unit 18 from which the workpiece 1 has been separated will hereinafter be designated by a numeral 18-1.

### (Storage Step)

FIG. 11 is a perspective view illustrating an example of a storage step 1005 in the workpiece management method illustrated in FIG. 2. FIG. 12 is a perspective view depicting a cassette for use in another example of the storage step 1005 in the workpiece management method illustrated in FIG. 2. The storage step 1005 is a step that stores the resin sheet 17 from which the workpiece 1 has been separated.

In the storage step 1005, the frame unit 18-1 that includes the resin sheet 17 from which the workpiece 1 has been separated is held in a coin-stack type cassette 40 with the annular frame 15 being still bonded on the outer edge portion of the resin sheet 17 as illustrated in FIG. 11, and is stored for a preset and predetermined period. The coin-stack type cassette 40 illustrated in FIG. 11 is a holder container that holds a plurality of workpieces 1 in a vertically stacked relation. The coin-stack type cassette 40 enables to insert the workpieces 1 through a top end opening 42 and to take out the workpieces 1 through the top end opening 42.

As illustrated in FIG. 11, the coin-stack type cassette 40 includes a cylindrical wall 41 having the top end opening 42, a cut-out portion 43 formed in the cylindrical wall 41, and a base plate 44. The cylindrical wall 41 is formed in a cylindrical shape and can internally hold frame units 18-1. The top end opening 42 is formed in a top end of the cylindrical wall 41 and allows the frame units 18-1 to pass inward. The cut-out portion 43 has been formed by cutting out a portion of the cylindrical wall 41 along an axis of the cylindrical wall 41. The base plate 44 is formed in a square plate shape, is disposed on a bottom end of the cylindrical wall 41, and closes the bottom end of the cylindrical wall 41.

The coin-stack type cassette 40 holds, inside the cylindrical wall 41, resin sheets 17 with annular frames 15 bonded on outer edge portions thereof, that is, frame units 18-1 and parting sheets 12, the parting sheets 12 being formed with a material softer than the workpiece 1, such as paper or synthetic resin, alternately in a stacked relation. In other words, the frame units 18-1 are held in a stacked relation with the parting sheets 12 in the coin-stack type cassette 40. Further, the frame units 18-1 and the parting sheets 12 are taken out of or inserted into the coin-stack type cassette 40 through the top end opening 42 by moving the frame units 18-1 and the parting sheets 12 in an up or down direction.

In the present invention, the frame units 18-1 from which the workpieces 1 have been separated may also be held and stored in a cassette 50 depicted in FIG. 12. The cassette 50 holds a plurality of frame units 18-1 at intervals in an up-down direction. As illustrated in FIG. 12, the cassette 50 includes a bottom wall 51, a pair of side walls 52 extending upright from opposite ends of the bottom wall 51 and opposing each other, a top wall 53 continuing to top ends of the paired side walls 52 and opposing the bottom wall 51 in the up-down direction, and a back wall 54 continuing to the paired side walls 52, the bottom wall 51, and the top wall 53. On mutually opposing inner surfaces of the side walls 52, support rails 55 are formed at a plurality of levels such that the annular frames 15 of the frame units 18-1 are mounted and supported at opposite end portions thereof on the support rails 55. The support rails 55 are linear in a horizontal direction and are arranged at intervals in the up-down direction.

The cassette 50 also includes an opening 56 surrounded by the paired side walls 52, the bottom wall 51, and the top wall 53. Through the opening 56, the frame units 18-1 are horizontally inserted onto and taken out from the respective support rails 55. The cassette 50 holds the frame units 18-1 on the support rails 55 of the respective levels at the intervals in the up-down direction, with the annular frames 15 being supported at the opposite end portions thereof on the support rails 55 of the respective levels. Further, each frame unit 18-1 is taken out of or inserted into the cassette 50 through the opening 56 by moving each frame unit 18-1 in the horizontal direction.

Owing to the printing of the identification information 19 on each resin sheet 17, the workpiece management method according to the first embodiment described above allows to determine which workpiece 1 was fixed on the resin sheet 17 even after the separation of the workpiece 1 from the resin sheet 17. The workpiece management method according to the first embodiment therefore has an advantageous effect that the processing circumstances can be determined based on the cut grooves 14 remaining as processed marks on the resin sheet 17 and the processed conditions of the workpiece 1 and device chips 7 can be specifically determined. In particular, the workpiece management method allows to determine chipping of the back surface 8 and wobbling of the cutting blade 35, because contaminant fragments (processing debris) occurred through processing and the cut grooves 14 remain on the resin sheet 17. Consequently, the workpiece management method according to the first embodiment brings about an advantageous effect that the difficulties in an investigation on the cause of defects of the device chips 7 can be reduced.

### Second Embodiment

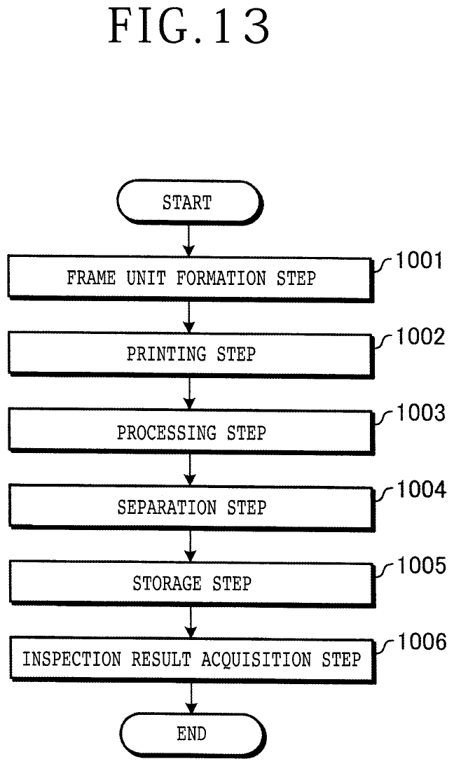

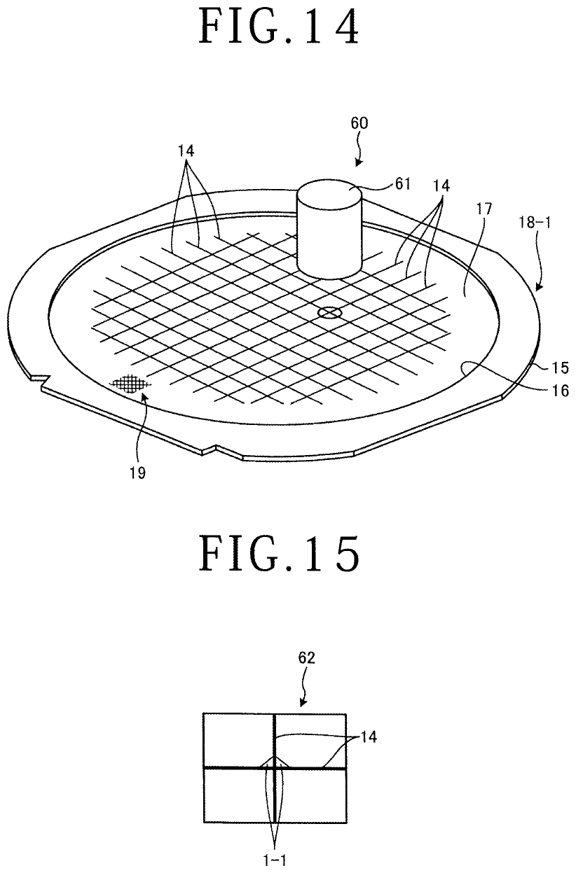

A workpiece management method according to a second embodiment of the present invention will be described with reference to FIGS. 13 to 15. FIG. 13 is a flow chart illustrating a flow of the workpiece management method according to the second embodiment. FIG. 14 is a perspective view illustrating an inspection result acquisition step in the workpiece management method illustrated in FIG. 13. FIG. 15 is a view illustrating an image of an essential part of a resin sheet obtained in the inspection result acquisition step in the workpiece management method illustrated in FIG. 13. In FIGS. 13 to 15, the same elements as those in the first embodiment are identified by the same reference numerals, and their description is omitted herein.

As illustrated in FIG. 13, the workpiece management method according to the second embodiment is the same as that of the first embodiment except for inclusion of an inspection result acquisition step 1006. The inspection result acquisition step 1006 is a step that, after performing the printing step 1002 and the separation step 1004, inspects processed conditions based on the cut grooves 14 remaining on the resin sheet 17, reads the identification information 19 on the inspected resin sheet 17, and acquires the processed conditions of the corresponding workpiece 1.

In order to conduct an investigation on the cause of any defect or the like if a defect or the like occurs on one or more of the individual device chips 7 manufactured by dividing the workpiece 1, the inspection result acquisition step 1006 in the second embodiment makes an inspection around the cut grooves 14 on the resin sheet 17. Therefore, the inspection result acquisition step 1006 is not performed on all the workpieces 1.

In the inspection result acquisition step 1006, the frame unit 18-1 with the one or more device chips 7 bonded as an object or the objects of inspection on the resin sheet 17 is taken out of the coin-stack type cassette 40 in which the frame unit 18-1 was stored in the storage step 1005, and an inspection device 60 holds the resin sheet 17 on the side of its base material layer on an unillustrated holding table. In the inspection result acquisition step 1006, the inspection device 60, as illustrated in FIG. 14, images the resin sheet 17 of the frame unit 18-1 by an imaging unit 61 at a location where the one or more device chips 7 as the object or the objects of the inspection are bonded, and acquires an image 62 illustrated by way of example in FIG. 15. If fragments 1-1 of the workpiece 1 are shown on edges of some cut grooves 14 in the image 62 as illustrated in FIG. 15, it is determined in the inspection result acquisition step 1006 that back side chipping (the edges of the cut grooves 14 are chipped on the back surface 8) occurred on the device chips 7 bonded at the location on the resin sheet 17 where the fragments 1-1 existed.

In the inspection result acquisition step 1006, the inspection device 60 reads the identification information 19 by an unillustrated reading unit and acquires the workpiece ID information 6 and the processing condition ID information 9. In the inspection result acquisition step 1006, the inspection device 60 acquires the processed conditions of the workpiece 1 indicated by the workpiece ID information 6.

Owing to the printing of the identification information 19 on each resin sheet 17, the workpiece management method according to the second embodiment can determine the processing circumstances based on the cut grooves 14 remaining on the resin sheet 17 and can specify the processed conditions of the workpiece 1 and device chips 7. Consequently, the workpiece management method according to the second embodiment, similar to that of the first embodiment, brings about the advantageous effect that the difficulties in an investigation on the cause of defects of the device chips 7 can be reduced.

### Third Embodiment

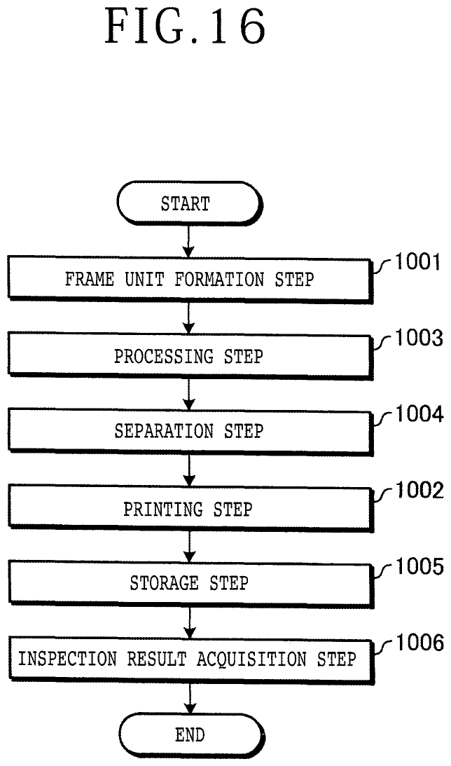

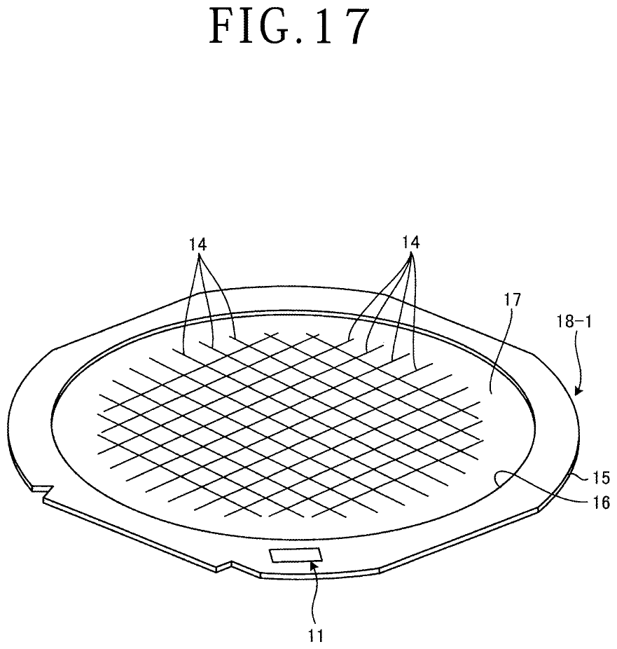

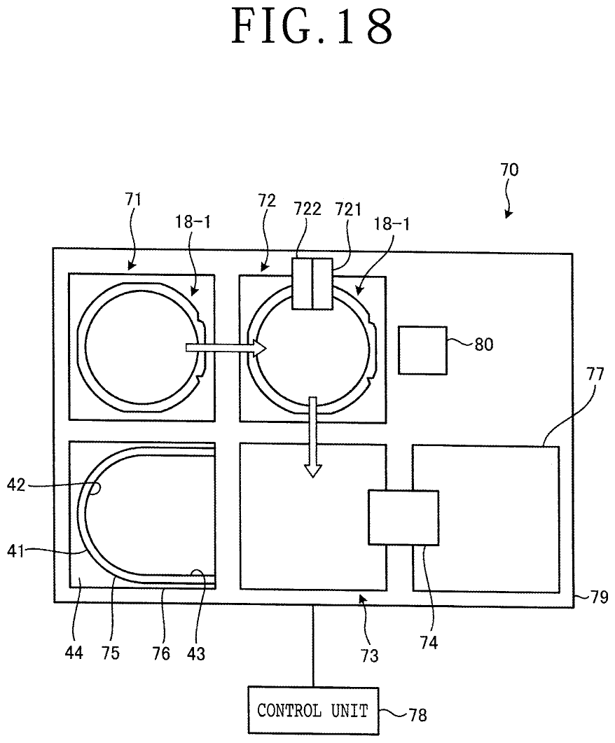

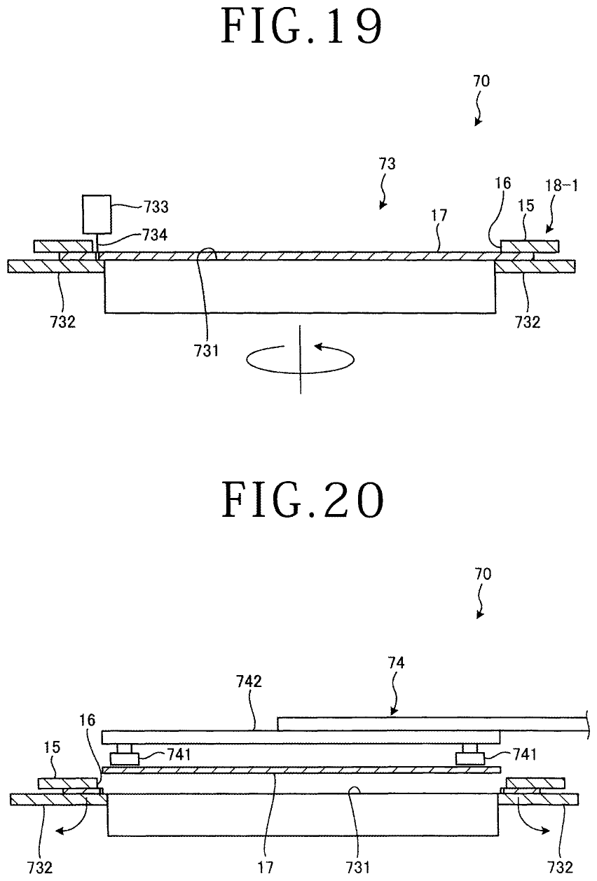

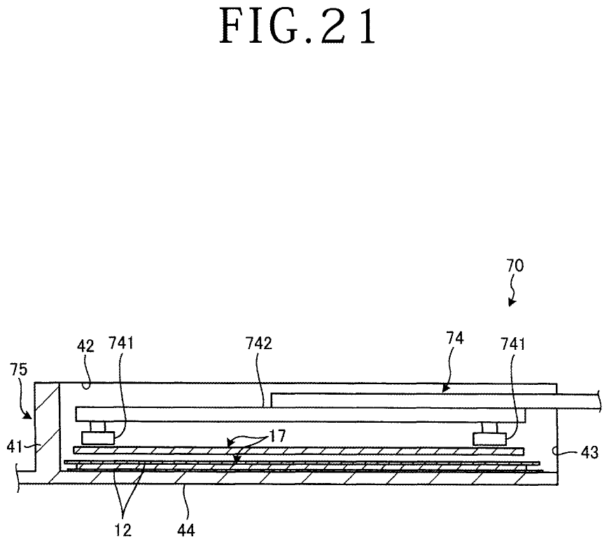

A workpiece management method according to a third embodiment of the present invention will be described with reference to FIGS. 16 to 21. FIG. 16 is a flow chart illustrating a flow of the workpiece management method according to the third embodiment. FIG. 17 is a perspective view depicting a frame unit after a separation step in the workpiece management method illustrated in FIG. 16. FIG. 18 is a plan view schematically illustrating a configuration of a sheet cutting machine that performs a printing step in the workpiece management method illustrated in FIG. 16. FIG. 19 is a side view illustrating a state where a resin sheet is cut along an inner edge of an annular frame in the printing step in the workpiece management method illustrated in FIG. 16, in which some elements are illustrated in cross-section. FIG. 20 is a side view illustrating a state where a resin sheet cut in the printing step in the workpiece management method illustrated in FIG. 16 is held, in which some elements are illustrated in cross-section. FIG. 21 is a cross-sectional view illustrating a state where the resin sheet is held in a holder case in the printing step in the workpiece management method illustrated in FIG. 16. In FIGS. 16 through 21, the same elements as those in the first and second embodiments are identified by the same reference numerals, and their description is omitted herein.

As illustrated in FIG. 16, the workpiece management method according to the third embodiment includes the frame unit formation step 1001, the processing step 1003, the separation step 1004, the printing step 1002, the storage step 1005, and the inspection result acquisition step 1006, and, after performing the frame unit formation step 1001, the processing step 1003, the separation step 1004, the printing step 1002, the storage step 1005, and the inspection result acquisition step 1006 are sequentially performed. In the workpiece management method according to the third embodiment, the frame unit formation step 1001, the processing step 1003, and the separation step 1004 are performed as in the first embodiment.

In the workpiece management method according to the third embodiment, frame identification (ID) information 11 is applied to the annular frame 15 of the frame unit 18-1 as depicted in FIG. 17. The frame ID information 11 is information for identifying each frame unit 18, in other words, ID information of the specific frame unit 18.

In the workpiece management method according to the third embodiment, the printing step 1002 is performed by a sheet cutting machine 70 illustrated in FIG. 18. The sheet cutting machine 70 cuts the resin sheet 17 of the frame unit 18-1 after the separation step 1004, the frame unit 18-1 being depicted in FIG. 17, along the inner edge of the annular frame 15, and holds the cut resin sheet 17 in a holder case 75.

As illustrated in FIG. 18, the sheet cutting machine 70 includes a cassette mount section 71, an unloading unit 80, a printing unit 72, a cutting unit (equivalent to a “resin sheet separation unit”) 73, a transfer unit 74, a sheet mount section 76 on which the holder case 75 (equivalent to a “resin sheet holding section”) is mounted, a parting sheet stock section 77 that stocks the parting sheets 12 in a stacked relation, and a control unit 78.

The cassette mount section 71 is arranged in a corner section of a machine main body 79 of the sheet cutting machine 70. The cassette 50 with the frame units 18-1 after the separation step 1004 held therein is mounted on an upper surface of the cassette mount section 71. The cassette mount section 71 supports the cassette 50 movably up and down in the vertical direction. The cassette 50 therefore holds each frame unit 18-1 with the cut grooves 14 formed on the resin sheet 17 after the workpiece 1 supported in the opening 16 of the annular frame 15 via the resin sheet 17 is cut and the cut workpiece 1 is separated from the resin sheet 17. On the upper surface of the cassette mount section 71, the cassette 50 is mounted with the opening 56 thereof directed toward a center of the machine main body 79.

The unloading unit 80 unloads the frame unit 18-1 from the cassette 50 mounted on the cassette mount section 71 and mounts the frame unit 18-1 on an unillustrated holding table of the printing unit 72.

The printing unit 72 prints the identification information 19 of the separated workpiece 1 on the resin sheet 17 of the frame unit 18-1 unloaded from the cassette 50 by the unloading unit 80. The printing unit 72 is arranged on the machine main body 79 at a location adjacent the cassette mount section 71, extends along a moving direction of the frame unit 18-1 when the frame unit 18-1 is unloaded from the cassette 50 mounted on the cassette mount section 71, and includes the holding table that holds the frame unit 18-1 via the resin sheet 17, a reading unit 721 that reads the frame ID information 11 of the frame unit 18-1 held on the holding table, and a printing head 722 that prints the identification information 19 on the resin sheet 17 of the frame unit 18-1. The printing head 722 prints the identification information 19 by irradiating a laser beam to the adhesive layer of the resin sheet 17. In the present invention, however, the printing method is not limited to such laser printing, and the identification information 19 may be printed, for example, by applying ink to the adhesive layer of the resin sheet 17.

The cutting unit 73 cuts the resin sheet 17, on which the identification information 19 has been printed by the printing unit 72, of the frame unit 18-1 along the inner edge of the annular frame 15, whereby the resin sheet 17 of the frame unit 18-1 is separated from the annular frame 15. The cutting unit 73 is arranged on the machine main body 79 at a location adjacent the printing unit 72 and extends along a direction interesting the moving direction of the frame unit 18-1 when the frame unit 18-1 is unloaded from the cassette 50 mounted on the cassette mount section 71. As illustrated in FIG. 19, the cutting unit 73 includes a sheet holding table 731 that holds the resin sheet 17 of the frame unit 18-1 on a side inner than the inner edge of the annular frame 15, a frame holding table 732 that holds the annular frame 15 of the frame unit 18-1, a cutting head 733 that cuts the resin sheet 17, and an unillustrated moving unit.

The cutting unit 73 holds, on the sheet holding table 731, the resin sheet 17 of the frame unit 18-1 on the side inner than the annular frame 15, holds the annular frame 15 of the frame unit 18-1 on the frame holding table 732, moves the cutting head 733 by the unillustrated moving unit relative to the frame unit 18-1 along the inner edge of the annular frame 15, and hence cuts the resin sheet 17 of the frame unit 18-1 along the inner edge of the annular frame 15. In the third embodiment, the cutting head 733 of the cutting unit 73 cuts the resin sheet 17 by irradiating a laser beam 734 to the adhesive layer of the adhesive sheet 17. In the present invention, however, the cutting method is not limited to such laser cutting, and the resin sheet 17 may be cut by causing a cutting edge to cut into the adhesive layer of the resin sheet 17. In the third embodiment, the cutting unit 73 is also configured to allow the frame holding table 732 to downwardly and outwardly pivot about its outer edge, so that the annular frame 15 held on the frame holding table 732 is dropped and held in an unillustrated case disposed below the frame holding table 732.

The transfer unit 74 transfers the frame unit 18-1 from the unillustrated holding table of the printing unit 72 onto the holding tables 731 and 732 of the cutting unit 73, transfers the cut resin sheet 17 from the sheet holding table 731 of the cutting unit 73 to the holder case 75, and transfers the parting sheet 12 from the parting sheet stock section 77 to the holder case 75. As illustrated in FIG. 20, the transfer unit 74 includes suction pads 741, a holding member 742 that holds the suction pads 741, and an unillustrated moving unit that moves the holding member 742 in a vertical direction and a horizontal direction. The suction pads 741 are non-contact Bernoulli pads which eject pressurized gas and, under a negative pressure generated by the gas, alternately hold the resin sheet 17 and the parting sheet 12 without contact to the resin sheet 17 and the parting sheet 12.

The parting sheet stock section 77 is arranged on the machine main body 79 at a location adjacent the cutting unit 73, and the sheet mount section 76 is arranged on the machine main body 79 at a location adjacent the cassette mount section 71 and the cutting unit 73. The holder case 75 mounted on the sheet mount section 76 has a configuration similar to the above-mentioned coin-stack type cassette 40. Therefore, portions identical to those of the coin-stack type cassette 40 are identified by the same reference numerals, and their description is omitted herein. The holder case 75 has a cut-out portion 43 which is formed to be greater than the outer diameter of the resin sheet 17 cut by the cutting unit 73 and is opposite to the cutting unit 73. Through the cut-out portion 43, the resin sheet 17 and the parting sheet 12 are inserted into the holder case 75 by the transfer unit 74. The holder case 75 therefore holds the resin sheet 17 separated from the annular frame 15 by the cutting unit 73.

The control unit 78 is a computer which includes a logic processing unit having a microprocessor such as a CPU, a storage device having a memory such as a ROM or a RAM, and an input/output interface device, and can perform computer programs. The control unit 78 controls individual elements that make up the printing unit 72 and allows the sheet cutting machine 70 to perform the printing step 1002.

In the control unit 78, each frame ID information 11 read by the reading unit 721, the ID information of the corresponding workpiece 1 bonded to the resin sheet 17, from which the reading unit 721 read the frame ID information 11, of the frame unit 18-1, and the corresponding set of processing conditions in the processing step 1003 have been stored beforehand together in association with one another.

In the printing step 1002 in the workpiece management method according to the third embodiment, the sheet cutting machine 70 takes out one of the frame units 18-1 which are after the separation step 1004, from the cassette 50 by the unloading unit 80, and holds the frame unit 18-1 on the unillustrated holding table of the printing unit 72. The sheet cutting machine 70 reads the frame ID information 11 by the reading unit 721 of the printing unit 72, and the control unit 78 extracts the workpiece ID information 6 that indicates the ID information of the specific workpiece 1 associated with the frame ID information 11, and the processing condition ID information 9 that indicates the set of processing conditions in the processing step 1003, the set of processing conditions being associated with the frame ID information 11. The control unit 78 of the sheet cutting machine 70 creates the identification information 19 that includes the workpiece ID information 6, the processing condition ID information 9, and the date information 10 indicating the date on which the processing step 1003 was performed.

The sheet cutting machine 70 brings the printing head 722 into opposition to an area of the resin sheet 17, the area being on a side inner than the inner edge of the annular frame 15, and prints the created identification information 19 on the resin sheet 17 by the printing head 722. The sheet cutting machine 70 transfers the frame unit 18-1, which includes the resin sheet 17 with the identification information 19 printed thereon, to the cutting unit 73 by the transfer unit 74, and holds the frame unit 18-1 on the holding tables 731 and 732. As illustrated in FIG. 19, the sheet cutting machine 70 cuts the resin sheet 17 along the inner edge of the annular frame 15 by the cutting head 733 and, as illustrated in FIG. 20, holds the cut resin sheet 17 by the transfer unit 74. As illustrated in FIG. 21, the sheet cutting machine 70 holds the cut resin sheet 17 in the holder case 75 by the transfer unit 74. In the third embodiment, the holder case 75 holds the resin sheets 17 and the parting sheets 12 alternately in a stacked relation. The resin sheets 17 held in the holder case 75 are stored for a preset and predetermined period in the storage step 1005.

In the workpiece management method according to the third embodiment, the inspection result acquisition step 1006 is performed as in the second embodiment. Owing to the printing of the identification information 19 on the resin sheet 17, the workpiece management method according to the third embodiment can determine the processing circumstances on the basis of the cut grooves 14 remaining on the resin sheet 17 and can specify the processed conditions of the workpiece 1 and device chips 7. Consequently, the workpiece management method according to the third embodiment, similar to that of the first embodiment, brings about the advantageous effect that the difficulties in an investigation on the cause of defects of the device chips 7 can be reduced.

The present invention shall not be limited to the above-described embodiments. In other words, the present invention can be practiced with various changes or alterations within the scope not departing from the spirit of the present invention. In the above-described embodiments, the processing machine 30 that performs the processing step 1003 is the cutting machine that cuts the workpiece 1. In the present invention, however, the processing machine 30 is not limited to such a cutting machine, and the processing machine 30 may be a laser processing machine that irradiates a laser beam of a wavelength having transmissivity through or absorption in the workpiece 1, a grinding machine that grinds the workpiece 1, or a polishing machine that polishes the workpiece 1. With the laser processing machine, the grinding machine that grinds the workpiece 1, or the polishing machine that polishes the workpiece 1, when a processing defect occurs, the resin sheet 17 may become discolored through heating or the like, and a burn mark may hence occur as what is called a processed mark. If these processing machines perform the processing step 1003, a burn mark may be detected as a processed mark on the resin sheet 17 in the inspection result acquisition step 1006. In the above-described embodiments, the resin sheet 17 is cut for its separation from the annular frame 15. In the present invention, however, the resin sheet 17 may be separated by peeling it off from the annular frame 15.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A workpiece management method comprising:
a frame unit forming step of forming a frame unit with a workpiece that has a front surface, the front surface including devices formed in respective regions defined by a plurality of intersecting streets, and that is supported in an opening of an annular frame via a resin sheet;
a printing step of, after performing the frame unit forming step, printing identification information of the workpiece on the resin sheet in an area between an outer periphery of the workpiece and an inner periphery of the annular frame;
a processing step of processing the workpiece by a processing machine;
a separation step of separating the processed workpiece from the resin sheet; and
a storage step of storing the resin sheet from which the workpiece has been separated.

2. The workpiece management method according to claim 1, further comprising:
an inspection result acquisition step of, after performing the printing step and the separation step, inspecting processed conditions from a processed mark remaining on the resin sheet, reading the identification information on the inspected resin sheet, and acquiring the processed conditions of the workpiece in association with the identification information.

3. The workpiece management method according to claim 1, wherein the identification information includes identification information of the workpiece, processing conditions in the processing step for the workpiece, or information regarding a date on which the processing step was performed on the workpiece.

4. A sheet cutting machine comprising:
a cassette mount section configured to mount thereon a cassette that holds a frame unit, the frame unit being formed from an annular frame and a workpiece supported in an opening of the annular frame via a resin sheet, after processing of the workpiece, formation of a processed mark on the resin sheet, and separation of the processed workpiece from the resin sheet;
an unloading unit configured to unload the frame unit from the cassette mounted on the cassette mount section;
a printing unit configured to print identification information of the separated workpiece on the resin sheet of the frame unit unloaded from the cassette;
a resin sheet separation unit configured to separate the resin sheet, the resin sheet remaining on the frame unit and carrying the identification information printed by the printing unit, from the annular frame; and
a resin sheet holding section configured to hold the resin sheet separated from the annular frame by the resin sheet separation unit.
